(19) United States
(12) Patent Application Publication
(10) Pub. No.: US 2025/0021730 A1
(43) Pub. Date: Jan. 16, 2025

(54) IDENTIFYING AND PREDICTING UNPLANNED DRILLING EVENTS

(71) Applicant: Saudi Arabian Oil Company, Dhahran (SA)

(72) Inventors: Dmitry Kovalev, Moscow (RU); Sergey Safonov, Moscow (RU); Arturo Magana Mora, Dhahran (SA); Mohammed AlJubran, Saihat (SA)

(21) Appl. No.: 18/714,322

(22) PCT Filed: Dec. 10, 2021
(86) PCT No.: PCT/RU2021/000563

§ 371 Date: May 29, 2024

(51) Int. Cl. G06F 30/28; G06F 30/27

(52) U.S. Cl. CPC G06F 30/28; G06F 30/27

(57) ABSTRACT

Methods and systems for drilling a well into a subsurface formation are configured for performing a downhole measurement to generate measurement-while-drilling (MWD) data; retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident; inputting the surface or subsurface data, generated based on the downhole measurement, into the machine learning model; generating, by the machine learning model based on the inputting, a classification output representing at least one unplanned drilling incident represented in the surface or subsurface data; and generating, based on the classification output, output data predicting at least one future unplanned drilling event.

### TECHNICAL FIELD

The specification generally relates to oil and gas exploration. More specifically, the specification describes methods and systems related to drilling wells into the deep subsurface and analysis of corresponding well data.

### BACKGROUND

Wells drilled into deep subsurface regions, such as for hydrocarbon production or other purposes, are associated with log data that represents well properties that provide guidance as to how the well should be drilled. To map geologic features in a subsurface region near or at the well bore, sensor data are acquired from the well bore. Measured sensor values provide an indication of changes in lithology or structure in regions of the subsurface.

During drilling, unplanned events have a significant impact on drilling operations. Unplanned events during drilling operation include stuck pipe incidents, circulation losses, and kicks or influxes. The severity of the drilling unplanned events may impact on non-productive time or even lead to abandonment of the borehole and sidetracking drilling.

### SUMMARY

This specification describes an approach for drilling wells into the deep subsurface, such as vertical or near-vertical wells. A system (such as a computer of a well system) is configured to identify one or more environmental effects in data acquired from a surface or subsurface region during drilling in the subsurface region. Generally, the surface and/or subsurface data include data acquired during drilling of a well. The data can include a resistivity value measured at or near a drill bit. The computer of the well system is configured to recognize features in the data to identify different unplanned drilling incidents in the data. The computer of the well system is configured to automatically determine which drilling incidents, such as drilling hazards, are occurring or may occur in the surface and/or subsurface data as represented in sensor data. Generally, an unsupervised model is trained on the whole data set. The data reduction process involves not only taking slices of initial data, but also decomposing data set into normal operations and abnormal operations components and taking just the latter after applying decomposition.

The unplanned drilling events can relate to prediction of drilling accidents or hazards. The computer of the well system is configured to process data from sensors on the surface (torque, weight on bit, among others) or in the subsurface (measurement- and logging-while drilling) to generate a prediction of when drilling accidents may occur. The computer of the well system is configured to execute a model for detecting and/or predicting unplanned events during drilling operations in order to avoid, reduce, and mitigate the risk of these events.

The methods and systems described in this specification are able to overcome technical issues with development of models for predicting accident occurrence. For example, prediction models based on machine-learning (ML) and deep-leaning (DL) for the prediction of drilling events described in this specification can overcome constraints of having limited training data and can be generalized to different wells. The machine learning models can satisfy a minimum accuracy requirement and are used to guide real-time operations. The models are configured to use scarce data from a limited number of considered wells for prediction of a given specific unplanned drilling event, even though all conditions and characteristics leading to that event may not be present in the training data. For example, the number of drilled wells with stuck pipe incidents is considerably smaller than the number of wells with no stuck pipe incidents. Training deep learning models generally requires a dataset that captures the joint distribution of the input and output variables. The models proposed do not require such data sets, as drilling as various parts of the joint distribution only occur in specific parts of the drilling operations. The machine learning models described in this specification are configured to predict drilling hazards without requiring training to identify every single drilling operation (such as tripping in/out, connection, reaming, among others). The machine learning models described in this specification overcome a data imbalance in which there would be many more samples capturing normal operations compared to those obtained from the drilling hazard incidents (such as stuck pipe, kick/influxes, or drilling mud circulation losses).

The implementations described throughout this specification can enable one or more of the following advantages. The machine learning models described in this specification enable a reduction in an amount of data for prediction of drilling hazards. The process described in this specification eliminates unnecessary data from normal operations in order to produce a subset of relevant data capturing specific anomalies or events, including the drilling hazard incident.

Accurate models for the prediction of unplanned drilling events may significantly reduce non-productive time and significantly reduce the probability of the abandonment of the borehole and sidetracking drilling. To achieve this objective, several specific systems for the unplanned events detection and prediction both in batches and in real time are used.

Conventional methods for predicting accidents based on detected environmental effects can depend on a judgement or experience of users, which is time consuming. Manual review can cause resulting inconsistencies between or among logs in different wells across a same field/reservoir because of differing judgements of different experts. The computer of the well system is configured for automatic identification and flagging of different environmental effects on surface and/or subsurface measurements, through a supervised machine learning approach. The machine learning model is trained to recognize the different environmental effects. Logic of the trained machine learning model is executed by the computer of the well system to predict environmental effect(s) for acquired data. In some implementations, the computer of the well system flags the data as being affected by the environmental effect. In some implementations, the identified environmental effects are corrected in a modeling workflow.

The one or more advantages are enabled by the following implementations.

In a general aspect, a process for drilling a well into a subsurface formation includes performing a well measurement to obtain surface or subsurface data; retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident; inputting the surface or subsurface data, generated based on the well measurement, into the machine learning model; generating, by the machine learning model based on the inputting, a classification output representing at least one unplanned drilling incident represented in the surface or subsurface data; and generating, based on the classification output, output data predicting at least one future unplanned drilling event.

In some implementations, the operations include drilling a well into the subsurface based on the output data predicting at least one future unplanned drilling event.

In some implementations, the process includes training the machine learning model prior to inputting the surface or subsurface data, wherein the training the machine learning model comprises: obtaining surface or subsurface data from one or more wells in an environment; extracting one or more components from the surface or subsurface data; generating, based on extracting, an identification function vector representing a reduced dataset of the surface or subsurface data, the reduced dataset including components associated with an increased anomaly score relative to extracted components associated with a decreased anomaly score; labeling the components of the identification function vector, wherein labeling the components associates each component with a drilling event; and inputting the identification function vector including the labeled components into the machine learning model to train the machine learning model.

In some implementations, the drilling event comprises at least one of a stuck pipe incident, a kick or influx incident, a drilling mud circulation loss incident, a break of drilling equipment, or a normal drilling event.

In some implementations, the surface or subsurface data include engineering logging variables for drilling a pipe, the engineering logging variables comprising at least one of a rotary torque, a standpipe pressure, a hook height, a weight on a drill bit, a hook load, a rate of penetration (ROP) of the subsurface, a rotations-per-minute (RPM) of the drill bit, and bottom hole assembly (BHA) inclination or orientation.

In some implementations, the surface or subsurface data include mud logging variables for drilling a pipe, the mud logging variables comprising at least one of a gamma ray value, a resistivity value, density and neutron-porosity of the formation, a flow-in rate, a flow-out rate, a fluid density, a yield point, an aplastic viscosity, and a dogleg severity value.

In some implementations, the machine learning model comprises a supervised machine learning model.

In some implementations, the process includes performing a data quality check for the measured surface or subsurface data, the data quality check configured to remove data comprising missing values, out of range values, saturated sensor values, or values from a damaged sensor.

In a general aspect, a system for drilling a well into a subsurface formation includes one or more sensors positioned in a well in a subsurface or near a well at a surface; at least one processor; and a memory storing instructions that, when executed by the at least one processor, cause the at least one processor to perform operations comprising: obtaining surface or subsurface data from the one or more sensors from a well measurement; retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident; inputting the surface or subsurface data, generated based on the well measurement, into the machine learning model; generating, by the machine learning model based on the inputting, a classification output representing at least one unplanned drilling incident represented in the surface or subsurface data; and generating, based on the classification output, output data predicting at least one future unplanned drilling event.

In a general aspect, one or more non-transitory computer-readable media storing instructions for drilling a well into a subsurface formation, wherein, when executed by at least one processor, the instructions cause the at least one processor to perform operations comprising: obtaining surface or subsurface data from one or more sensors for a well measurement; retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident; inputting the surface or subsurface data, generated based on the well measurement, into the machine learning model; generating, by the machine learning model based on the inputting, a classification output representing at least one unplanned drilling incident represented in the surface or subsurface data; and generating, based on the classification output, output data predicting at least one future unplanned drilling event.

The details of one or more embodiments of these systems and methods are set forth in the accompanying drawings and the description to be presented. Other features, objects, and advantages of these systems and methods will be apparent from the description and drawings, and from the claims.

### BRIEF DESCRIPTION OF DRAWINGS

FIG. 1 is a schematic view of a well drilling system.

FIG. 2 shows a process for identifying and predicting unplanned drilling events using a machine learning model.

FIG. 3 shows a process for indicator function analysis.

FIG. 4 shows an example data processing system.

FIG. 5 is a block diagram illustrating an example computer system used to provide computational functionalities associated with described algorithms, methods, functions, processes, flows, and procedures as described in the present disclosure, according to some implementations of the present disclosure. Like reference symbols in the various drawings indicate like elements.

### DETAILED DESCRIPTION

This specification describes an approach for drilling wells into the deep subsurface, such as vertical or near-vertical wells. A drilling system (such as a well system) is configured to identifying or predicting unplanned drilling events, such as drilling anomalies, based on data acquired from a surface region and/or a subsurface region during drilling. A computer of the well system is configured to train and execute machine learning models for identifying the unplanned well events, such as stuck pipe, kick/influxes, drilling mud circulation losses, tight spots, tool failures, among others.

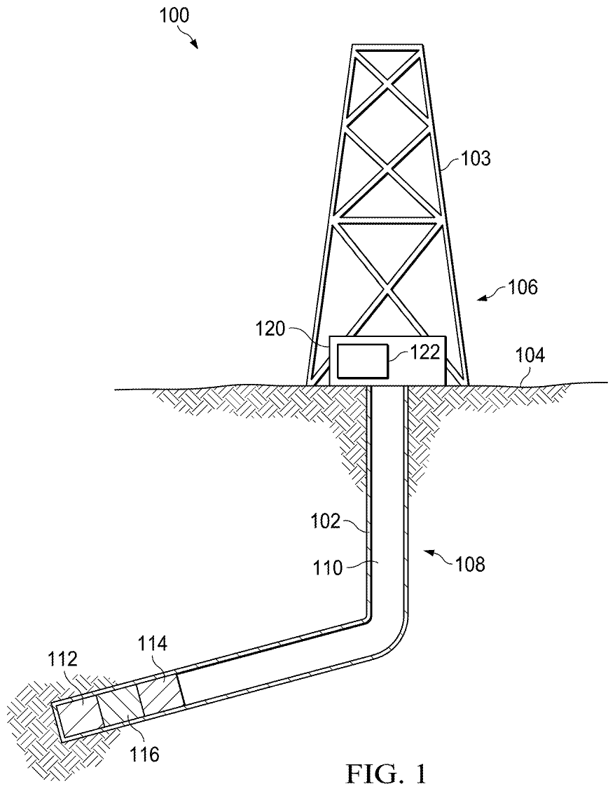

FIG. 1 is a side cross-sectional view of an example well system 100. The example well system 100 includes a wellbore 102 within a geologic formation 104. At an uphole end of the wellbore 102 is a topside facility 106. The topside facility 106 includes any pumps, compressors, separators, and safety devices for wellbore operations. From the topside facility extends a workstring 108 extending from the topside facility 106 towards a downhole end of the wellbore 102. In some implementations, a derrick 103 can be used to support the workstring 108. While illustrated as being supported by the derrick 103, the workstring can be supported in other ways, for example, by a coiled tubing truck.

The workstring 108 itself can include coiled tubing 110, production tubing, a drill pipe, or any other type of tubular suitable for wellbore operations. Throughout this disclosure, coiled tubing 110 is primarily described as the tubular for the workstring 108; however, other tubulars can be used without departing from this disclosure. As illustrated, the workstring 108 includes a length of coiled tubing 110 with a vibration sub 112 attached to a downhole end of the coiled tubing 110. Similarly, a logging tool 114 is attached to the coiled tubing 110 near the downhole end of the coiled tubing 110. Between the vibration sub 112 and the logging tool 114 is a vibration damper 116 attached to the length of coiled tubing 110. While illustrated as including a vibration sub at a downhole end of the workstring 108, the vibration sub 112 can be placed anywhere along the length of the workstring 108 as the vibration assists in the workstring 108 traveling through the wellbore 102. Regardless of the location of the vibration sub 112, a vibration damper 116 is located between a logging tool 114 and a vibration sub 112.

The logging tool 114 or a sensor tool 120 of the well system 100 provide real-time data from measurements near the drill bit or at the surface to a computer 122 during the drilling process in a subterranean formation 100 across multiple geological layers 104, 106 and 108. The sensor tools 110 or logging tool 114 provide formation measurements such as gamma ray, resistivity, density and neutron-porosity of the formation and also well data such a hook height, a weight on the drill bit, a hook load, a stand pipe pressure, a torque on the drill bit, a flow-in rate, a flow-out rate, a rate of penetration (ROP) of the subsurface, a rotations-per-minute (RPM) of the drill bit, a fluid density, a yield point, an aplastic viscosity, bottom hole assembly (BHA) inclination or orientation, and a dogleg severity value. In some implementations, the one or more of the sensor(s) 110, 114 are positioned on the surface rather than in the subsurface.

The computer 122 of the well system 100 is configured to augment raw drilling data from surface and subsurface sensors with additional information using feature engineering. Because data characterizing unplanned drilling events are considerably less compared to the data for other operations, deriving robust data-driven models for such an unbalanced dataset results in errors in the predictions of unplanned well events. The computer 122 of the well system 100 executes an unsupervised learning model used to remove normal operations from drilling operations data. Once normal operations data are removed from the drilling data, a single identification function is computed for each well. In some implementations, data above the unsupervised model threshold are used for further analysis, labelling, and semi-supervised learning of unplanned drilling events, which leads to lowering their false positive rates, increasing overall accuracy.

Generally, the raw drilling data include data acquired during drilling of a well. In some examples, the drilling data are acquired from hardware coupled to a BHA. The drilling data can include logging while drilling (LWD) data measured in the well bore and during drilling, and can be extracted periodically in real-time. The data acquired as part of drilling data can include resistivity data (such as ohm-m), representing attenuation and phase-shift resistivities at different transmitter spacings and frequencies. The data can include a resistivity value measured at or near a drill bit. The resistivity data can include deep directional resistivities. The drilling data can include sonic data, such as compressional slowness (Δtc) or shear slowness (Δts) data. In some implementations, sonic data is being transmitted in real-time to the surface. Other drilling data can be gathered, including nuclear magnetic resonance (NMR) data, formation pressure and fluid sampling, borehole imaging, neutron porosity measurements, density measurements, or gamma ray measurements. In some implementations, the drilling data include real-time drilling parameters at the surface and from downhole as either time-series or table data. The drilling data can include values for hook height, weight on bit, hook load, a stand pipe pressure, a torque value, flow-in rate, a flow-out rate, an ROP, RPM, a fluid density, a yield point, a plastic viscosity, BHA inclination, and dogleg severity, among other data, including more complex calculations, such as torque and drag, hydraulics, vibrations, etc.

The computer 122 of the well system 100 is configured to recognize features in the drilling data. The computer 122 of the well system 100 receives values of drilling parameters at the surface and from downhole locations as either time-series or table data. In some implementations, the data are received and processed in real-time. Here, real-time refers to receiving the data as the data are generated by the one or more sensors 110, processing these data, and outputting a result. In real-time processing, delays between data generation from sensors and output data generation from the computer 122 of the well system 100 are generally due to transmission and processing latency, rather than due to storage of data by the computer 122 for later processing. In some implementations, the data from the sensors 110 or logging tool 114 includes one or more values for a hook height, a weight on the drill bit, a hook load, a stand pipe pressure, a torque on the drill bit, a flow-in rate, a flow-out rate, a rate of penetration of the subsurface, a rotations-per-minute of the drill bit, a fluid density, a yield point, an aplastic viscosity, bottom hole assembly (BHA) inclination or orientation, a dogleg severity value, and so forth. In some implementations, other data (such as environmental data including resistivity data) can be received and processed by the computer 122 of the well system 100.

The computer 122 of the well system 100 performs a data-reduction processing to remove data representing normal operations from received data. The received data includes the dataset for all wells. The data reduction step is performed in an unsupervised manner, meaning that the computer 122 of the well system 100 implement artificial intelligence unsupervised models (i.e., those that do not require labels such as principal component analysis, clustering, distance models, among others) to automatically identify data representing normal operations which are to be removed from the dataset as they do not provide useful information for downstream analyses. Normal operations include nominal drilling operations, or drilling operations in which there are no anomalies or events representing drilling hazards (also called drilling faults, drilling errors, or drilling incidents) of the drilling process. Drilling hazards can include stuck pipe incidents, kicks or influxes, drilling mud circulation losses, and so forth.

The computer 122 of the well system 100 determines the components of data, which are referred to normal operation, to remove. The unsupervised model is trained on the whole dataset. As normal operations constitute the vast majority of the data, it becomes possible to identify normal operations components and remove these components from the dataset. The normal operations components are inferred from the unsupervised model. The computer 122 of the well system 100 concatenates the remaining sensor data for the set of observed wells.

The computer 122 of the well system 100 extracts the selected components from the sensor data. The selected components include sensor data that are received during normal activity during drilling. The computer 122 of the well system 100 extracts several components from the entire dataset (all observed wells). Extracting the components by the computer 122 of the well system 100 results in subtracting data representing normal operations from the dataset.

The computer 122 of the well system 100 adjusts the remaining data for consistency. For example, the remaining data, which represents drilling hazard events, are time adjusted so that associated time stamps are correct for the remaining data. The computer 122 of the well system 100 preprocesses the well drilling data by filling-in missing values by interpolation, scaling, and anomalous value detection and replacement. The anomalous values in this context refer to individual values that are out of range, missing, null, or otherwise represent erroneous data. These may result from a sensor issue or noise within a sensor signal.

The computer 122 of the well system 100 defines data windows in the data for identifying individual hazard incidents. The computer 122 of the well system 100 is configured to extract well data in the data window surrounding the drilling hazard incident, for example two days before and one day after [−2, +1 days] the event or 10 hours and one hour after the event [−10, +1 hours], which are determined based on the desired objective of the model. The computer 122 of the well system 100 removes non-important columns for the extracted data. These columns may include data irrelevant to a particular drilling hazard incident. For example, BHA inclination and RPM may be irrelevant data for a first type of incident, while ROP and flow-in or flow-out may be irrelevant to a second type of incident. The particular data removed at this step can be specific to the type of incident, which can be predefined or computationally done by using feature selection algorithms (genetic algorithms, information gain, chi squared, and recursive feature elimination, among others). In some implementations, the data windows are user-defined. In some implementations, a data time step is defined, and data of this time step resolution are used, while other data are discarded.

The computer 122 of the well system 100, after defining a data window with a given length and time step, applies the data window to the dataset. The computer 122 of the well system 100 applies the data window continuously (e.g., in a sliding manner across data entries) to the dataset constructed as previously described. The computer 122 of the well system 100 concatenates extracted slices of data into a single dataset. Although drilling parameters can provide meaningful information for the data-driven models, the computer 122 of the well system 100 can employ feature-engineering techniques to generate additional features to further improve the performance of the models, as subsequently described. The additional engineering tools may consist of moving averages, standard deviations, kurtosis, skewness, linear trend, change in mean, Gaussian filters, differencing, among others, as well as more complex calculations derived from the raw data, such as torque and drag, hydraulics, vibrations, equivalent circulating density, among others.

The computer 122 of the well system 100 reduces the dataset further by computing an indicator function. The computer 122 of the well system 100 can use a change point analysis. Change point analysis includes converting a multivariate time series of drilling data into an identification function. The example of the ID function is the probability of the unplanned event happening during drilling operations at specified timestamp. The computer 122 of the well system 100 uses an automatic threshold estimation process for drilling accident identification function. The threshold estimation process is fully automatic and is based on statistical analysis (e.g., classifiers or other machine learning approaches). Generally, a data point exceeding the determined threshold is treated as representing a possible unplanned drilling event.

In some implementations, an expert analyzes multiple consecutive points augmented with additional parameters, such as its shape, form, square, etc. The computer 122 of the well system 100 uses these augmented data are as labels for the classification of unplanned drilling events. The computer 122 of the well system 100 uses the identified data in a semi-supervised model configured for learning from stuck pipe incidents and anomalies. The computer 122 of the well system 100 tests the constructed model on previously unprocessed data. The computer 122 of the well system 100 is configured to generate output data, such as warning data indicating an estimated time remaining before a next drilling incident. The computer 122 of the well system 100 can output this warning or alarm to local or remote users, such as through a user interface or data transmission.

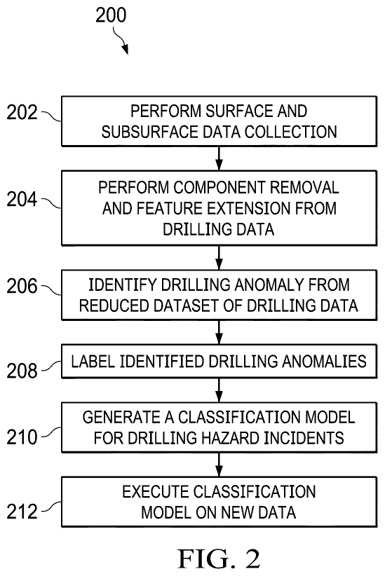

Turning to FIG. 2, a process 200 for identifying and predicting unplanned drilling events using a machine learning model is shown. In the process 200, a data processing system (e.g., the computer 122 of the well system 100 described in relation to FIG. 1) is configured to perform (202) measurements using surface (e.g., surface torque, weight on bit, stand pipe pressure, mud flow in/out, among others) and subsurface sensors (e.g., measurement-while-drilling and logging-while-drilling, such as with sensors 110 transmitting data in real-time through mud-pulse telemetry, electromagnetic telemetry, or wired pipe). Generally, surface or subsurface data are a main part of a well geophysical survey and enable the computer 122 of the well system 100 to monitor the condition of the well at all stages of well construction. Surface and subsurface data contains mechanical parameters of drilling the well. For example, the surface and subsurface data can be divided into two groups of variables. A first group of variables includes engineering logging variables measured by the downhole sensors and/or obtained by the computation, such as torque and weight on bit (near the bit), downhole temperature, rotational speed and smoothness of the rotation, among others. MWD aim to provide directional surveys and some drilling mechanics information near the bit (torque, WOB, downhole temperature, RPM, etc.). A second group of variables includes mud logging variables that indirectly indicate a state of downhole formations, such as mud properties and flow rate. The dataset can be generated in a form of a table or a plurality of log entries. In some implementations, when the new data are generated, the new data are concatenated with the previous log entries or table in the dataset. In some implementations, the data are generated in real time or near real time as the drilling is occurring. The computer 122 of the well system 100 is configured to concatenate the collected data. The computer 122 of the well system 100 concatenates the datasets from each available well transforms the data from the different wells into a vector space. In some implementations, the data are transformed by the computer 122 of the well system 100 by using principal component analysis (PCA), probabilistic latent component analysis, or other statistical analyses. For example, PCA is commonly used as a dimensionality reduction method where a smaller number of components can be used to represent high dimensional data (i.e., data samples defined by a large number of attributes).

The computer 122 of the well system 100 is configured to classify extracted components as representing normal operations or anomalous operations. The computer 122 of the well system 100 is configured to perform (204) the classification and remove data representing normal operations from the data. By removing these components, the computer 122 of the well system 100 is able to train machine learning models for identifying abnormal drilling operations. To perform feature extraction, the computer 122 of the well system 100 removes components representing the normal operations to generate a more compact and meaningful representation of drilling incidents. When the remaining data is used to train or fit a model, the parameters of the model are informative. Since many of generated features can be correlated or uninformative, the computer 122 of the well system 100 performs multivariate analysis to reduce the feature dimension space. The examples of correlated features are bit depth and hook load, tank volume (active) and stand pipe pressure, volume tank and flow rate of the pump, weight on bit and hook load among others.

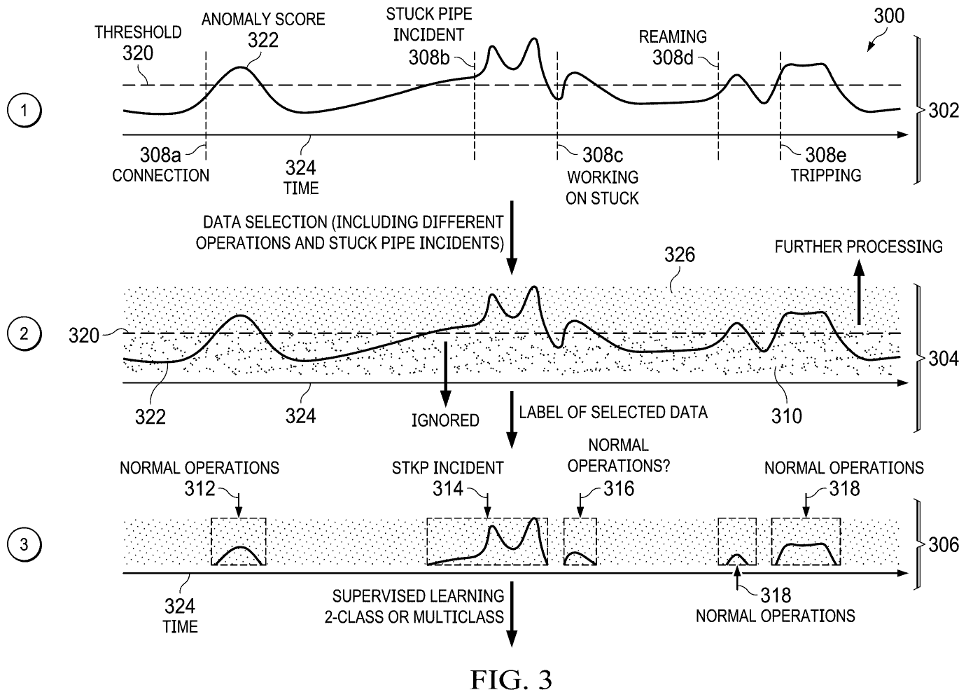

The computer 122 of the well system 100 is configured to identify (206) drilling anomalies from the reduced dataset. The data reduction converts multivariate vectors of extracted drilling data into the identification function vector. Generally, an increase or decrease in values of the function vector occurs when a change in operations in original data occurs. The computer 122 of the well system 100 is configured to analyze only the data values which exceed threshold samples during further processing, as described in relation to FIG. 3. The computer 122 of the well system 100 is configured to analyze the data related to anomalies that are identified, including the data form, area, and distribution of these data samples. The computer 122 of the well system 100 matches these data with unplanned drilling events using time stamps.

The computer 122 of the well system 100 is configured to label (208) the data related to identified anomalies in the drilling process. In some implementations, data labeling can be performed by experts only for identification function values which exceed pre-defined threshold. In some implementations, the computer 122 of the well system 100 performs labeling by performing data matching. For example, to label an operation, the computer 122 of the well system 100 can use labels for normal and abnormal operations. In another example, the computer 122 of the well system 100 is configured to split abnormal operations into multiple categories, such as stuck pipe incidents, wash-outs, mud circulation losses, breaks of drilling, and so forth. The computer 122 of the well system 100 or expert can review additional data for context, such as drilling logs and drilling morning reports, when generating labels for the identified anomalies.

The computer 122 of the well system 100, based on the generated labels, generates (210) a data-driven classification model. The classification model can include a machine learning model such as a convolutional neural network (CNN) or any statistical classifier. The computer 122 of the well system 100 incorporates additional features, such as form, area, slope, and so forth into the model as features. The computer 122 of the well system 100 executes (212) the classifier to predict and classify unplanned drilling events with real-time MWD. In some implementations, the classifier is retrained after a new drilling dataset is acquired by the computer 122 of the well system 100.

FIG. 3 shows a process 300 for indicator function analysis, in which the dataset is reduced and features of the data are identified for generation of training data. The process of FIG. 3 shows three main steps 302, 304, and 306 for preparing surface and subsurface data for training the classifier. In a first step 302, the aggregated data are received. The data are converted into component values such as using principal component analysis (PCA). An anomaly score 322 is determined from the unsupervised model. The steps for producing the anomaly score 322 are the following: 1) unsupervised model is trained on the whole dataset, 2) from the model the uncertainty score is extracted, 3) uncertainty score is normalized and converted into anomaly score. The anomaly score is associated with the data in a time series over as time period 324. A threshold value 320 is predetermined based on training data, as previously described. The threshold can be set by an expert if needed without retraining model. Another example for setting the threshold is based on the scores of the classification model 210 by choosing it in such manner that the scores are maximized.

The threshold is set by statistical analysis or by expert review. The procedure for choosing the threshold can include the following: 1) calculate total area under the anomaly score curve, 2) calculate area between the anomaly score curve and threshold as function of threshold, 3) the difference between them should be the same to the total percentage of non-productive time in all work.

In FIG. 3, a sequence of events 308a-e are shown to illustrate the process 300 of identifying the unplanned hazard incidents. The events include a connection event 308a, a stuck pipe incident 308b, a working on stuck pipe period 308c, a reaming event 308d, and a tripping event 308e. Some of the events 308a-e are normal operations, such as the connection event 308a, the reaming event 308d, and the tripping event 308e. The events 308a-e have not yet been identified at step 302 but are shown in FIG. 3 for illustrating the process 300.

At step 304, the computer 122 of the well system 100 is configured to compare the anomaly score 322 to the threshold 320 over the time period 324. When the anomaly score 322 satisfies (exceed) the threshold 320, the computer 122 of the well system 100 saves the surface or subsurface data and/or the components of the surface or subsurface data for that time period for further processing 326. When the anomaly value 322 does not satisfy (is below) the threshold 320, the computer 122 of the well system 100 ignores or discards 310 that surface or subsurface data or its component values. This data reduction ensures that normal operations do not bias the classifier too far towards normal operations.

At step 306, the remaining data for processing by the computer 122 of the well system 100 are shown. Several events are remaining in the surface or subsurface data. A first event 312 represents normal operations, and follows the connection event 308a. A second event 314 represents the stuck pipe incident 308b. A third event 316 represents subsequent work on the stuck pipe 308c. The fourth and fifth events 318 represent normal operations of reaming event 308d and a tripping event 308e. These extracted events are labeled the computer 122 of the well system 100 or an expert and used to train the classifier, as described previously. In some implementations, the extracted events are called an identification function. The identification function can be stored as labeled data by the computer 122 of the well system 100. The labeled data are used by the computer 122 of the well system 100 to train the machine learning models (classifiers).

The computer 122 is configured to generate the classifier, as previously described in relation to FIG. 2. Output of the classifier can include probability values. In some implementations, the output data include a confusion matrix. The classification values represent a likelihood that a given drilling incident is included in the surface or subsurface data. The computer 122 generates the classification value(s) for the surface or subsurface data by applying the machine learning model (such as executing machine learning model logic) on the surface or subsurface data. The MWD can be input into the machine learning model, which then outputs the classification values. Examples of the machine learning models used can include support vector machines (SVMs), Bayes models, decision forests, and regression models such as linear or logistic models. In some implementations, a random forest model (machine learning technique) is used. The reduced dataset is input into one or more of these models for training the models. During drilling, surface or subsurface data are input into the trained model.

The computer 122 of the well system 100 is configured to generate an indication, such as an alert or flag, specifying each drilling incident predicted from a particular set of data (such as for a well). The one or more flags or alerts are associated with the MWD or wireline data. The flags can be input into a workflow configured to correct the surface or subsurface data to predict an anomaly will occur. The prediction can be used to guide drilling or exploration activities, reducing exploration and drilling costs.

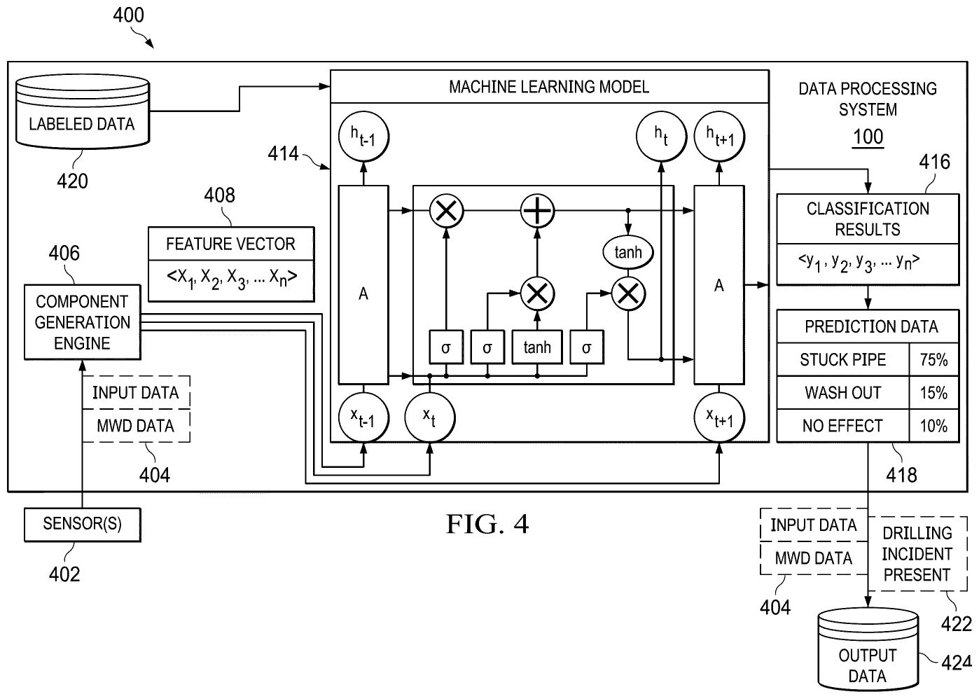

FIG. 4 represents a data processing system 400 for performing the processes described in this specification. The data processing system 400 can include the computer 122 of the well system 100 described in relation to FIGS. 1-3. In the data processing system 400, sensor(s) 402 are configured to measure surface or subsurface data. The sensor(s) 402 can include, for example, electrodes that are placed downhole in the well bore, gyroscopes, tachymeters, flow sensors, and so forth. The input data 404 includes the surface or subsurface data previously described. In this example, a support vector machine (SVM) is being used as the machine learning model. In this example, the input data are transformed into component data 408 by the component generation engine 406 so that the input data is in a format that can be processed by the SVM machine learning model 414. The machine learning model 414 is trained with labeled data 420, such as from a data store, that are generated as described in relation to FIG. 3. The data processing system 400 generates a feature vector 408 that represents the MWD in component form. If any additional preprocessing are required to prepare the values from the MWD for processing by the machine learning model 414, the transform engine (not shown) can perform this preprocessing. Such preprocessing is performed by the data processing system 400 configured to adjust the format of any input data as needed for the particular machine learning model selected for processing the surface or subsurface data.

The machine learning model 414, trained by labeled data 420 as described previously in relation to FIG. 3, is configured to receive the feature vector 408 (or a transformed version of the vector) representing the surface or subsurface data and output classification results 416. The results 416 can include a confusion matrix representing classification outcomes for each of the possible outputs. For example, here, three environmental effects unplanned drilling events data 418 are shown as possible including a stuck pipe, wash out, or no effect (though generally more effects can be analyzed as previously described). As shown in prediction data 418, a probability or weight value is associated with each outcome. Here, a conductive stuck pipe is weighted with the greatest value. The data processing system 400 outputs a classification that the stuck pipe is present in output data 422. The output data 422 are presented on a user interface. In some implementations, the output data 422 are stored in a data store 424 or transmitted to a remote computing system for presentation or further processing by the remote data processing system.

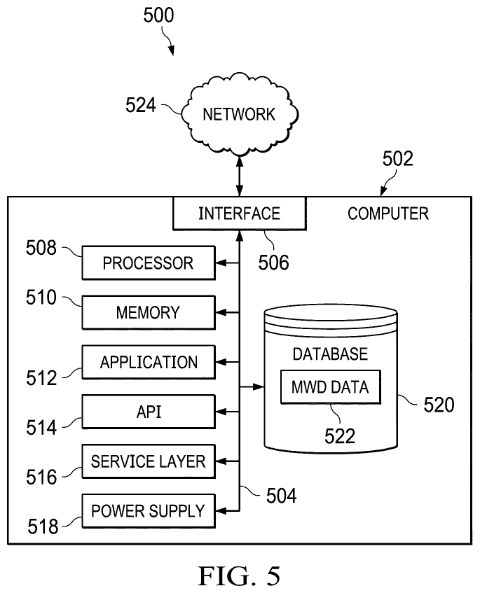

FIG. 5 is a block diagram of an example data processing system 500 used to provide computational functionalities associated with described algorithms, methods, functions, processes, flows, and procedures described in the present disclosure, according to some implementations of the present disclosure. The illustrated computer 502 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 502 can include input devices such as keypads, keyboards, and touch screens that can accept user information. Also, the computer 502 can include output devices that can convey information associated with the operation of the computer 502. The information can include digital data, visual data, audio information, or a combination of information. The information can be presented in a graphical user interface (UI) (or GUI).

The computer 502 can serve in a role as a client, a network component, a server, a database, a persistency, or components of a computer system for performing the subject matter described in the present disclosure. The illustrated computer 502 is communicably coupled with a network 530. In some implementations, one or more components of the computer 502 can be configured to operate within different environments, including cloud-computing-based environments, local environments, global environments, and combinations of environments.

At a high level, the computer 502 is an electronic computing device operable to receive, transmit, process, store, and manage data and information associated with the described subject matter. According to some implementations, the computer 502 can also include, or be communicably coupled with, an application server, an email server, a web server, a caching server, a streaming data server, or a combination of servers.

The computer 502 can receive requests over network 530 from a client application (for example, executing on another computer 502). The computer 502 can respond to the received requests by processing the received requests using software applications. Requests can also be sent to the computer 502 from internal users (for example, from a command console), external (or third) parties, automated applications, entities, individuals, systems, and computers.

Each of the components of the computer 502 can communicate using a system bus 504. In some implementations, any or all of the components of the computer 502, including hardware or software components, can interface with each other or the interface 506 (or a combination of both), over the system bus 504. Interfaces can use an application programming interface (API) 514, a service layer 516, or a combination of the API 514 and service layer 516. The API 514 can include specifications for routines, data structures, and object classes. The API 514 can be either computer-language independent or dependent. The API 514 can refer to a complete interface, a single function, or a set of APIs.

The service layer 516 can provide software services to the computer 502 and other components (whether illustrated or not) that are communicably coupled to the computer 502. The functionality of the computer 502 can be accessible for all service consumers using this service layer. Software services, such as those provided by the service layer 516, can provide reusable, defined functionalities through a defined interface. For example, the interface can be software written in JAVA, C++, or a language providing data in extensible markup language (XML) format. While illustrated as an integrated component of the computer 502, in alternative implementations, the API 514 or the service layer 516 can be stand-alone components in relation to other components of the computer 502 and other components communicably coupled to the computer 502. Moreover, any or all parts of the API 514 or the service layer 516 can be implemented as child or sub-modules of another software module, enterprise application, or hardware module without departing from the scope of the present disclosure.

The computer 502 includes an interface 506. Although illustrated as a single interface 506 in FIG. 5, two or more interfaces 506 can be used according to particular needs, desires, or particular implementations of the computer 502 and the described functionality. The interface 506 can be used by the computer 502 for communicating with other systems that are connected to the network 530 (whether illustrated or not) in a distributed environment. Generally, the interface 506 can include, or be implemented using, logic encoded in software or hardware (or a combination of software and hardware) operable to communicate with the network 530. More specifically, the interface 506 can include software supporting one or more communication protocols associated with communications. As such, the network 530 or the hardware of the interface can be operable to communicate physical signals within and outside of the illustrated computer 502.

The computer 502 includes a processor 508. Although illustrated as a single processor 508 in FIG. 5, two or more processors 508 can be used according to particular needs, desires, or particular implementations of the computer 502 and the described functionality. Generally, the processor 508 can execute instructions and can manipulate data to perform the operations of the computer 502, including operations using algorithms, methods, functions, processes, flows, and procedures as described in the present disclosure.

The computer 502 also includes a database 520 that can hold data (for example, surface or subsurface data 522) for the computer 502 and other components connected to the network 530 (whether illustrated or not). For example, database 520 can be an in-memory, conventional, or a database storing data consistent with the present disclosure. In some implementations, database 520 can be a combination of two or more different database types (for example, hybrid in-memory and conventional databases) according to particular needs, desires, or particular implementations of the computer 502 and the described functionality. Although illustrated as a single database 520 in FIG. 5, two or more databases (of the same, different, or combination of types) can be used according to particular needs, desires, or particular implementations of the computer 502 and the described functionality. While database 520 is illustrated as an internal component of the computer 502, in alternative implementations, database 520 can be external to the computer 502.

The computer 502 also includes a memory 510 that can hold data for the computer 502 or a combination of components connected to the network 530 (whether illustrated or not). Memory 510 can store any data consistent with the present disclosure. In some implementations, memory 510 can be a combination of two or more different types of memory (for example, a combination of semiconductor and magnetic storage) according to particular needs, desires, or particular implementations of the computer 502 and the described functionality. Although illustrated as a single memory 510 in FIG. 5, two or more memories 510 (of the same, different, or combination of types) can be used according to particular needs, desires, or particular implementations of the computer 502 and the described functionality. While memory 510 is illustrated as an internal component of the computer 502, in alternative implementations, memory 510 can be external to the computer 502.

The application 512 can be an algorithmic software engine providing functionality according to particular needs, desires, or particular implementations of the computer 502 and the described functionality. For example, application 512 can serve as one or more components, modules, or applications. Further, although illustrated as a single application 512, the application 512 can be implemented as multiple applications 512 on the computer 502. In addition, although illustrated as internal to the computer 502, in alternative implementations, the application 512 can be external to the computer 502.

The computer 502 can also include a power supply 518. The power supply 518 can include a rechargeable or non-rechargeable battery that can be configured to be either user- or non-user-replaceable. In some implementations, the power supply 518 can include power-conversion and management circuits, including recharging, standby, and power management functionalities. In some implementations, the power-supply 518 can include a power plug to allow the computer 502 to be plugged into a wall socket or a power source to, for example, power the computer 502 or recharge a rechargeable battery.

There can be any number of computers 502 associated with, or external to, a computer system containing computer 502, with each computer 502 communicating over network 530. Further, the terms “client,” “user,” and other appropriate terminology can be used interchangeably, as appropriate, without departing from the scope of the present disclosure. Moreover, the present disclosure contemplates that many users can use one computer 502 and one user can use multiple computers 502.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware-or software-based (or a combination of both hardware-and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

A number of embodiments of these systems and methods have been described. Nevertheless, it will be understood that various modifications may be made without departing from the spirit and scope of this disclosure. Accordingly, other embodiments are within the scope of the following claims.

What is claimed is:

1. A method for drilling a well into a subsurface formation, the method comprising:
performing a well measurement to obtain surface or subsurface data;
retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident;
inputting the surface or subsurface data, generated based on the well measurement, into the machine learning model;
generating, by the machine learning model based on the inputting, a classification output representing at least one unplanned drilling incident represented in the surface or subsurface data; and
generating, based on the classification output, output data predicting at least one future unplanned drilling event.

2. The method of claim 1, further comprising:
drilling a well into the subsurface based on the output data predicting at least one future unplanned drilling event.

3. The method of claim 1, further comprising training the machine learning model prior to inputting the surface or subsurface data, wherein the training the machine learning model comprises:
obtaining surface or subsurface data from one or more wells in an environment;
extracting one or more components from the surface or subsurface data;
generating, based on extracting, an identification function vector representing a reduced dataset of the surface or subsurface data, the reduced dataset including components associated with an increased anomaly score relative to extracted components associated with a decreased anomaly score;
labeling the components of the identification function vector, wherein labeling the components associates each component with a drilling event; and
inputting the identification function vector including the labeled components into the machine learning model to train the machine learning model.

4. The method of claim 3, wherein the drilling event comprises at least one of a stuck pipe incident, a kick or influx incident, a drilling mud circulation loss incident, a break of drilling equipment, or a normal drilling event.

5. The method of claim 1, wherein the surface or subsurface data include engineering logging variables for drilling a pipe, the engineering logging variables comprising at least one of a rotary torque, a standpipe pressure, a hook height, a weight on a drill bit, a hook load, a rate of penetration (ROP) of the subsurface, a rotations-per-minute (RPM) of the drill bit, and bottom hole assembly (BHA) inclination or orientation.

6. The method of claim 1, wherein the surface or subsurface data include mud logging variables for drilling a pipe, the mud logging variables comprising at least one of a gamma ray value, a resistivity value, density and neutron-porosity of the formation, a flow-in rate, a flow-out rate, a fluid density, a yield point, an aplastic viscosity, and a dogleg severity value.

7. The method of claim 1, wherein the machine learning model comprises a supervised machine learning model.

8. The method of claim 1, further comprising:
performing a data quality check for the measured surface or subsurface data, the data quality check configured to remove data comprising missing values, out of range values, saturated sensor values, or values from a damaged sensor.

9. A system for drilling a well into a subsurface formation, the system comprising:
one or more sensors positioned in a well in a subsurface or near a well at a surface;
at least one processor; and
a memory storing instructions that, when executed by the at least one processor, cause the at least one processor to perform operations comprising:
obtaining surface or subsurface data from the one or more sensors from a well measurement;
retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident;
inputting the surface or subsurface data, generated based on the well measurement, into the machine learning model;
generating, by the machine learning model based on the inputting, a classification output representing at least one unplanned drilling incident represented in the surface or subsurface data; and
generating, based on the classification output, output data predicting at least one future unplanned drilling event.

10. The system of claim 9, the operations further comprising:
drilling a well into the subsurface based on the output data predicting at least one future unplanned drilling event.

11. The system of claim 9, the operations further comprising training the machine learning model prior to inputting the surface or subsurface data, wherein the training the machine learning model comprises:
obtaining surface or subsurface data from one or more wells in an environment;
extracting one or more components from the surface or subsurface data;
generating, based on extracting, an identification function vector representing a reduced dataset of the surface or subsurface data, the reduced dataset including components associated with an increased anomaly score relative to extracted components associated with a decreased anomaly score;
labeling the components of the identification function vector, wherein labeling the components associates each component with a drilling event; and
inputting the identification function vector including the labeled components into the machine learning model to train the machine learning model.

12. The system of claim 11, wherein the drilling event comprises at least one of a stuck pipe incident, a kick or influx incident, a drilling mud circulation loss incident, a break of drilling equipment, or a normal drilling event.

13. The system of claim 9, wherein the surface or subsurface data include engineering logging variables for drilling a pipe, the engineering logging variables comprising at least one of a rotary torque, a standpipe pressure, a hook height, a weight on a drill bit, a hook load, a rate of penetration (ROP) of the subsurface, a rotations-per-minute (RPM) of the drill bit, and bottom hole assembly (BHA) inclination or orientation.

14. The system of claim 9, wherein the surface or subsurface data include mud logging variables for drilling a pipe, the mud logging variables comprising at least one of a gamma ray value, a resistivity value, density and neutron-porosity of the formation, a flow-in rate, a flow-out rate, a fluid density, a yield point, an aplastic viscosity, and a dogleg severity value.

15. The system of claim 9, wherein the machine learning model comprises a supervised machine learning model.

16. The system of claim 9, the operations further comprising:
performing a data quality check for the surface or subsurface data, the data quality check configured to remove data comprising missing values, out of range values, saturated sensor values, or values from a damaged sensor.

17. One or more non-transitory computer-readable media storing instructions for drilling a well into a subsurface formation, wherein, when executed by at least one processor, the instructions cause the at least one processor to perform operations comprising:
obtaining surface or subsurface data from one or more sensors for a well measurement;
retrieving a machine learning model that is trained using labeled surface or subsurface data, the labeled surface or subsurface data representing one or more unplanned drilling incidents each causing a respective data signature in the surface or subsurface data, each respective data signature being associated with a corresponding label identifying the unplanned drilling incident;
inputting the surface or subsurface data, generated based on the well measurement, into the machine learning model;
generating, by the machine learning model based on the inputting, a classification output representing at least one unplanned drilling incident represented in the surface or subsurface data; and
generating, based on the classification output, output data predicting at least one future unplanned drilling event.

18. The one or more non-transitory computer readable media of claim 17, the operations further comprising:
drilling a well into the subsurface based on the output data predicting at least one future unplanned drilling event.

19. The one or more non-transitory computer readable media of claim 17, the operations further comprising training the machine learning model prior to inputting the surface or subsurface data, wherein the training the machine learning model comprises:
obtaining surface or subsurface data from one or more wells in an environment;
extracting one or more components from the surface or subsurface data;
generating, based on extracting, an identification function vector representing a reduced dataset of the surface or subsurface data, the reduced dataset including components associated with an increased anomaly score relative to extracted components associated with a decreased anomaly score;
labeling the components of the identification function vector, wherein labeling the components associates each component with a drilling event; and
inputting the identification function vector including the labeled components into the machine learning model to train the machine learning model.

20. The one or more non-transitory computer readable media of claim 19, wherein the drilling event comprises at least one of a stuck pipe incident, a kick or influx incident, a drilling mud circulation loss incident, a break of drilling equipment, or a normal drilling event.
